(19) United States
(12) Patent Application Publication
(10) Pub. No.: US 2026/0282966 A1
(43) Pub. Date: Sep. 17, 2026

(54) DISCRETE PITCH ADAPTER SUBSTRATES FOR CHIPLETS

(71) Applicant: Tenstorrent USA, Inc., Austin, TX (US)

(72) Inventors: Aydin Nabovati, Toronto (CA); Daniel William Bailey, Rollingwood, TX (US)

(21) Appl. No.: 19/256,663

(22) Filed: Jul. 1, 2025

Related U.S. Application Data
(60) Provisional application No. 63/770,033, filed on Mar. 11, 2025.

(51) Int. Cl. H01L 23/538; H01L 23/00; H01L 25/00; H01L 25/10

(52) U.S. Cl. CPC H10W 70/65; H10W 70/611; H10W 90/00; H10W 70/635; H10W 90/724

(57) ABSTRACT

Systems and methods related to discrete pitch adapter substrates for chiplets are disclosed herein. A system may comprise a first chiplet with a first set of chiplet connections having a first pitch, a second chiplet with a second set of chiplet connections having a second pitch, a first discrete pitch adapter substrate, and a second discrete pitch adapter substrate. The first discrete pitch adapter substrate may comprise a first set of conductive paths which may connect the first set of chiplet connections to a set of shared substrate connections. The second discrete pitch adapter substrate may comprise a second set of conductive paths which may connect the second set of chiplet connections to the set of shared substrate connections. By using discrete pitch adapter substrates to convert any connection pitch to another pitch, chiplets of different connection pitches may be used on the same package at a low cost.

### CROSS REFERENCE TO RELATED APPLICATIONS

This application claims the benefit of U.S. Provisional Patent Application No. 63/770,033, filed on Mar. 11, 2025, which is incorporated by reference herein in its entirety for all purposes.

### BACKGROUND

Chips must meet certain spacings requirements between their external contacts so that the chip may be compatible with external systems such as the connections on a printed circuit board on which the chip will be attached. In some systems, a chip's external contacts have spacings that are too small for the external systems to which it will be attached; and therefore, a substrate is placed between the chip's external contacts and the external system. The substrate has one set of contacts that are compatible with the chip, another set of contacts that are compatible with the external system, and a set of wires that connect the two sets of contacts.

In situations in which a chip's external contacts have spacings that are too small for the substrate to which it will be attached, an intermediate system such as an interposer can be introduced which has one set of contacts that are compatible with the chip, another set of contacts that are compatible with the substrate, and a set of wires that connect the two sets of contacts.

Chiplets are small integrated circuits with external contacts that often have finer pitches than the packages for more traditional chips. The fine pitch of the chiplets means that they will often require interposers, in addition to a substrate, to interface with other external systems. This increases the complexity of some packaging and assembly configurations and may lead to yield issues.

### SUMMARY

This disclosure relates to discrete pitch adapter substrates for chiplets. The connection pitch (e.g., bump pitch) of any chiplet may be determined by the pads (e.g., LB pads) on the last metal layer of the silicon. Once a chiplet is out of the factory, these pads are fixed, meaning the bump pitch may not be able to be changed afterwards. For products based on chiplets, it is possible to use chiplets of different sources and combine them into one complex system through the package. Depending on the bump pitch, the packaging technology will be different. As long as the bump pitch values are close, there is a possibility of mixing chiplets of different bump pitches, but that comes with process complexity and depending on the manufacturing design rules, the mixed pitch span can be very limited.

The two main categories of packaging types are standard packaging and advanced packaging. In standard packaging, all the chiplets are directly mounted on a substrate. Standard packaging may be for bump pitches larger than around 90 um; there is not currently a well-defined limit for the lower end of bump pitch that is used in standard packaging. As there is not a single bump pitch that defines standard packaging currently, pitches of 140 um, 130 um, 110 um, 90 um are very commonly seen on standard packaging.

Advanced packaging is for chiplets of finer bump pitches. Such fine pitches are needed to increase the number of connections to a chiplet. As a substrate may not support the assembly of fine pitch chiplets, advanced packaging may use a transition layer between the chiplet and substrate. This transition layer can be silicon interposer, a redistribution layer (RDL), an RDL with a bridge, or just a bridge between chiplets. Similar to standard packaging, the bump pitch used in advanced packaging can vary between different designs. Currently, pitches of 65 um, 55 um, 45 um are commonly seen in different advanced packages. A limitation here is that once a chiplet is out of the factory, the bump pitches are fixed, and therefore the application of a certain chiplet on different products becomes limited.

A method herein is disclosed to use a discrete pitch adapter substrate (e.g., a simplified RDL) to convert any connection pitch to another pitch. This will enable the use of chiplets of very different bump pitches on the same package. For example, chiplets of three different bump pitches of pitch I, pitch II, and pitch III may be assembled on the same package. Discrete pitch adapter substrates may be used to convert chiplets of pitch I and pitch II to pitch III, consistent with the third chiplet. The discrete pitch adapter substrates may enable the use of chiplets of different connection pitches on the same package without the need for expensive silicon re-spins. The discrete pitch adapter substrate also reduces the cost and lead-time of advanced packaging. It is expected that the cost and lead-time of the discrete pitch adapter substrate to be a fraction of a full RDL that is commonly used in advanced packaging. The discrete pitch adapter substrates may be discrete in that they are independent physical elements which can be independently attached to a given chiplet. The discrete pitch adapter substrates may have a footprint which is equal or similar to that of the chiplet to which it will be attached. Bumps are an example of a connection type. Chip connections may be pads, solder balls, bumps, pillars, micro-bumps, leads, or other conductive connections.

In specific embodiments of the invention, a system is provided. The system comprises: a first chiplet with a first set of chiplet connections having a first pitch; a second chiplet with a second set of chiplet connections having a second pitch, the second pitch being different than the first pitch; and a first discrete pitch adapter substrate comprising a first set of conductive paths. The first set of conductive paths connects the first set of chiplet connections to a set of shared substrate connections, the set of shared substrate connections having a third pitch different than the first pitch and the second pitch. The system also comprises a second discrete pitch adapter substrate comprising a second set of conductive paths. The second set of conductive paths connects the second set of chiplet connections to the set of shared substrate connections.

In specific embodiments of the invention, a method of packaging a system is provided. The method comprises electrically coupling a first discrete pitch adapter substrate to a first chiplet via a first set of chiplet connections. A first chiplet-adapter interface of the first discrete pitch adapter substrate has a first pitch. The first chiplet has the first pitch. The first set of chiplet connections directly couple the first chiplet-adapter interface with the first chiplet. The method also comprises electrically coupling a second discrete pitch adapter substrate to a second chiplet via a second set of chiplet connections. A second chiplet-adapter interface of the second discrete pitch adapter substrate has a second pitch. The second chiplet has the second pitch. The second pitch is different than the first pitch. The second set of chiplet connections directly couple the second chiplet-adapter interface with the second chiplet. The method also comprises electrically coupling the first discrete pitch adapter substrate to a shared substrate via a first set of substrate connections. A first adapter-substrate interface of the first discrete pitch adapter substrate has a third pitch. The shared substrate has the third pitch. The third pitch is different than the first pitch and the second pitch. The first set of substrate connections directly couple the first adapter-substrate interface with the shared substrate. The method also comprises electrically coupling the second discrete pitch adapter substrate to the shared substrate via a second set of substrate connections. A second adapter-substrate interface of the second discrete pitch adapter substrate has the third pitch. The second set of substrate connections directly couple the second adapter-substrate interface with the shared substrate.

In specific embodiments of the invention, a system is provided. The system comprises a plurality of chiplets, each chiplet of the plurality of chiplets having a set of chiplet connections with a unique pitch. The unique pitch of each chiplet of the plurality of chiplets is different. The system also comprises a set of shared substrate connections, a pitch of the set of shared substrate connections being different than the unique pitches of the plurality of chiplets; and a plurality of discrete pitch adapter substrates, each discrete pitch adapter substrate being uniquely associated with a chiplet in the plurality of chiplets. Each discrete pitch adapter substrate comprises a set of conductive paths. Each discrete pitch adapter substrate connects the set of chiplet connections of the uniquely associated chiplet to the set of shared substrate connections. The system also comprises a substrate comprising a set of metal wiring layers. The set of metal wiring layers of the substrate couples the set of shared substrate connections to an external set of connections.

### BRIEF DESCRIPTION OF THE DRAWINGS

The accompanying drawings illustrate various systems, methods, and embodiments of various other aspects of the disclosure. A person with ordinary skills in the art will appreciate that the illustrated element boundaries (e.g., boxes, groups of boxes, or other shapes) in the figures represent one example of the boundaries. It may be that in some examples one element may be designed as multiple elements or that multiple elements may be designed as one element. In some examples, an element shown as an internal component of one element may be implemented as an external component in another, and vice versa. Furthermore, elements may not be drawn to scale. Non-limiting and non-exhaustive descriptions are described with reference to the following drawings. The components in the figures are not necessarily to scale, emphasis instead being placed upon illustrating principles.

FIG. 1 provides examples of standard packaging, advanced packaging, and advanced packaging with a discrete pitch adapter substrate in accordance with specific embodiments of the inventions disclosed herein.

FIG. 2 provides examples of different packaging configurations for chiplets in accordance with specific embodiments of the inventions disclosed herein.

FIG. 3 provides examples of discrete pitch adapter substrates adapting chiplet connection pitches to the shared substrate pitch in accordance with specific embodiments of the inventions disclosed herein.

FIG. 4 provides an example of a method for packaging a system with discrete pitch adapter substrates in accordance with specific embodiments of the inventions disclosed herein.

### DETAILED DESCRIPTION

Reference will now be made in detail to implementations and embodiments of various aspects and variations of systems and methods described herein. Although several exemplary variations of the systems and methods are described herein, other variations of the systems and methods may include aspects of the systems and methods described herein combined in any suitable manner having combinations of all or some of the aspects described.

Different systems and methods for discrete pitch adapter substrates for chiplets in accordance with the summary above are described in detail in this disclosure. The methods and systems disclosed in this section are nonlimiting embodiments of the invention, are provided for explanatory purposes only, and should not be used to constrict the full scope of the invention. It is to be understood that the disclosed embodiments may or may not overlap with each other. Thus, part of one embodiment, or specific embodiments thereof, may or may not fall within the ambit of another, or specific embodiments thereof, and vice versa. Different embodiments from different aspects may be combined or practiced separately. Many different combinations and sub-combinations of the representative embodiments shown within the broad framework of this invention, that may be apparent to those skilled in the art but not explicitly shown or described, should not be construed as precluded.

This disclosure relates to discrete pitch adapter substrates for chiplets. Chiplets are small integrated circuits that can have finer pitches than the packages for more traditional chips. The connection pitch of any chiplet may be determined by the pads on the last metal layer of the silicon. Once a chiplet is out of the factory, these pads are fixed, meaning the bump pitch may not be able to be changed afterwards. For products based on chiplets, it is possible to use chiplets of different sources and combine them into one complex through the package. Depending on the bump pitch, the packaging technology may be different.

A system may comprise a plurality of chiplets, where the chiplets have connections with different (e.g., unique) pitches. The system may include a set of shared substrate connections, where the pitch of the set of shared substrate connections may be different than one or more of the pitches of the plurality of chiplets. The system may include a plurality of discrete pitch adapter substrates to convert the chiplet connection pitch to the substrate connection pitch. Each discrete pitch adapter substrate may be uniquely associated with a chiplet in the plurality of chiplets. Each discrete pitch adapter substrate may comprise a set of conductive paths. Each discrete pitch adapter substrate may connect the set of chiplet connections of the uniquely associated chiplet to the set of shared substrate connections.

By using discrete pitch adapter substrates to convert any connection pitch to another pitch, chiplets of very different connection pitches may be used on the same package. This enables the use of chiplets with finer pitches, which allows for a larger number of connections between chiplets, potentially increasing bandwidth. The discrete pitch adapter substrates may convert finer pitches to a coarser pitch, such that chiplets with different original pitches may have the same pitch after conversion and can be processed together on the same substrate. The discrete pitch adapter substrates may reduce the cost and lead-time compared to full interposers commonly used in advanced packaging. In some cases, the discrete pitch adapter substrates may enable the use of chiplets of different connection pitches on the same package without the need for expensive silicon re-spins of the chiplets themselves.

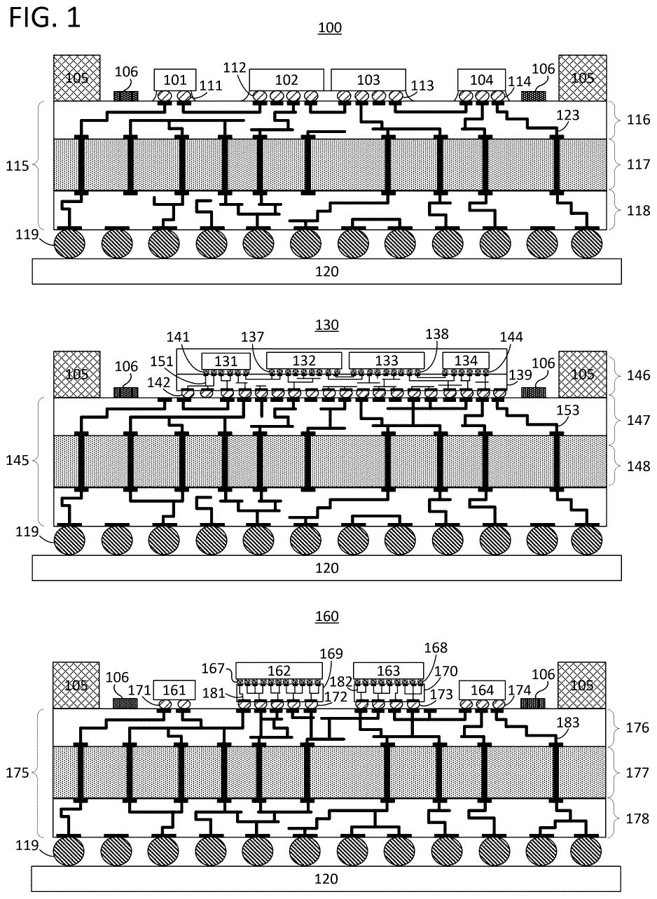

FIG. 1 illustrates examples of standard packaging (system 100), advanced packaging (system 130), and advanced packaging with a discrete pitch adapter substrate (system 160) in accordance with specific embodiments of the inventions disclosed herein. Systems 100, 130, and 160 include chiplets and a substrate. Specific features of systems 100, 130, and 160 as shown may be optional. For example, stiffeners 105, electrical components 106, substrate cores, external connections 119, and printed circuit board (PCB) 120 may be optional. The chiplet system on the substrate may be referred to as a system of a package (SoP). Stiffeners 105 may provide mechanical strength for the overall SoP. Electrical components 106 (e.g., capacitors) may be passive devices on the SoP.

Although illustrated as circular, connections (e.g., bumps) such as connections 111, 112, 113, 114, 119, 137, 138, 141, 142, 144, 167, 168, 171, 172, 173, and 174, may, in practice, look more like columns. These connections may be made of copper or another conductive material. Each chiplet 101, 102, 103, 104, 131, 132, 133, 134, 161, 162, 163, and 164 may have die pads that connect to the bumps or microbumps that are under the chiplet. Bumps and microbumps may encompass a variety of connections. For example, external connections 119 (e.g., contacts) may be solder balls. Pillars may also be types of bumps. Although shown as spherical, in practice, connections may look more like pillars. Microbumps may be similar to bumps but at a finer pitch.

System 100 illustrates an example of standard packaging. Chiplets 101, 102, 103, and 104 may have the same pitch. Substrate 115 may include conductive paths 123 (e.g., a bunch of wires) connecting the connections 111, 112, 113, and 114 of chiplets 101, 102, 103, and 104 (respectively) to external connections 119. Connections 111, 112, 113, and 114 may be bumps. Conductive paths 123 may traverse substrate portion 116, structural core 117, and substrate portion 118 of substrate 115. External connections 119 may connect conductive paths 123 to PCB 120.

System 130 illustrates an example of advanced packaging. Chiplets 131, 132, 133, and 134 may have a finer pitch than those of chiplets 101, 102, 103, and 104. Redistribution layer 139 (e.g., an interposer) may include conductive paths 151 connecting connections 141, 137, 138, and 144 of chiplets 131, 132, 133, and 134 (respectively) to shared substrate connections 142 (e.g., intermediate connections). Connections 141, 137, 138, and 144 may be microbumps. Microbumps may be bumps that are finer than a certain pitch. Substrate 145 may include conductive paths 153 (e.g., a bunch of wires) connecting shared substrate connections 142 to external connections 119. Shared substrate connections 142 may be bumps. Conductive paths 153 may traverse substrate portion 146, structural core 147, and substrate portion 148 of substrate 145. External connections 119 may connect conductive paths 153 to PCB 120.

System 160 illustrates an example of advanced packaging with discrete pitch adapter substrates 169 and 170 to convert the pitch of connections 167 and 168 to the pitch of connections 172 and 173 (respectively). Adapting the pitch on a per-chiplet basis enables using chiplets of very different bump pitches on the same package. Chiplets 161, 162, and 163 may have different pitches. Chiplets 161 and 164 may have the same pitch. Discrete pitch adapter substrate 169 may include conductive paths 181 (e.g., a bunch of wires) connecting chiplet connections 167 of chiplet 162 to substrate connections 172. Chiplet connections 167 may be microbumps. Discrete pitch adapter substrate 170 may include conductive paths 182 (e.g., a bunch of wires) connecting chiplet connections 168 of chiplet 163 to substrate connections 173. Chiplet connections 168 may be microbumps. Discrete pitch adapter substrates 169 and 170 may act as simplified redistribution layers. Substrate 175 may include conductive paths 183 (e.g., a bunch of wires) connecting substrate connections 172 and 173 to external connections 119. Conductive paths 183 may traverse substrate portion 176, structural core 177, and substrate portion 178 of substrate 175. External connections 119 may connect conductive paths 183 to PCB 120.

In the example of system 160, chiplets of three different bump pitches of pitch I (chiplet 162), pitch II (chiplet 163), and pitch III (chiplets 161 and 164) are assembled on the same package. Discrete pitch adapter substrate 169 may be used to convert chiplet 162 of pitch I to pitch III; discrete pitch adapter substrate 170 may be used to convert chiplet 163 of pitch II to pitch III. Chiplets 161 and 164 may be directly connected to substrate connections 171 and 174 respectively. Substrate connections 171, 172, 173, and 174 may be subsets of a set of shared substrate connections. The set of shared substrate connections may have pitch III and may be bumps.

The system may include a plurality of discrete pitch adapter substrates; each discrete pitch adapter substrate being uniquely associated with a chiplet in the plurality of chiplets. Discrete pitch adapter substrates 169 and 170 may be discrete in that they are physically separate components. The discrete pitch adapter substrates may be physically touching (directly or via a packaging material), however, the pitch adapter substrates may be manufactured as separate components or have been split apart at some point in the manufacturing process. In specific embodiments, discrete pitch adapter substrates may be electrically isolated from each other or may be electrically connected via metal wiring layers in the substrate. In specific embodiments, discrete pitch adapter substrates may not be directly electrically connected to each other (e.g., any conductive path between discrete pitch adapters may go through the substrate). Discrete pitch adapter substrate 169 may comprise a set of conductive paths 181 (e.g., set of metal wiring layers) and discrete pitch adapter substrate 170 may comprise a set of conductive paths 182. Discrete pitch adapter substrate 169 may connect (e.g., couple) the set of chiplet connections 167 of the uniquely associated chiplet 162 to substrate connections 172. Discrete pitch adapter substrate 170 may connect (e.g., couple) the set of chiplet connections 168 of the uniquely associated chiplet 163 to substrate connections 173.

In specific embodiments, the system may include one or more chiplets without (e.g., not associated with any) discrete pitch adapter substrate. For example, chiplets 161 and 164 both have chiplet connections that match the pitch of the set of shared substrate connections. In this case, the subset of the set of shared substrate connections 171 and 174 may be a set of chiplet connections. Chiplets 161 and 164 may therefore be directly connected to the set of shared substrate connections (e.g., without a discrete pitch adapter substrate intermediating).

Substrate 175, PCB 120, discrete pitch adapter substrate 169 and discrete pitch adapter substrate 170 may each be composed of layers of copper tracing and dielectric at different scales. For example, the width of a copper trace in PCB 120 may be about 100 um; the width of copper trace in substrate 175 may be about 10 um; and the width of copper trace in discrete pitch adapter substrates 169 and 170 may be about 1 um. In this case, the “width” of the copper trace may refer to the dimension of the conductive paths (e.g., 181, 182, 183) out of the page.

Structural core 177 may act as a backbone or chassis for substrate 175 and the portions of conductive paths 183 within structural core 177 may have different properties than the portions of conductive paths 183 within substrate portions 176 and 178. For example, the portions of conductive paths 183 within structural core 177 may not have complicated routing but rather may be relatively straight (e.g., vertical) lines. Substrate portions 176 and 178, by comparison, may have more complicated routing with bends and intersections. Structural core 177 may be made of fiber glass material or another strong material. The portions of conductive paths 183 within structural core 177 may be plated through holes (PTHs). Holes may be drilled into structural core 177 and the holes may be plated with a conductive material (e.g., copper) to create electrical connections (e.g., hollow wires) between the top and bottom of structural core 177. In specific embodiments, the copper-lined holes may be filled with resin. The resin may prevent solder migration and strengthen the PTHs. Structural core 177 may make up a large portion of substrate 175. For example, if substrate 175 is 100 um thick, then structural core 177 may be 85 um. The features of structural core 177 may not be present in discrete pitch adapter substrates 169 or 170. Structural core 177 may be optional; in specific embodiments, substrate 175 may not include structural core 177. For example, a system like system 160 that is part of a mobile device may not include a structural core within the substrate.

Substrate 175 may include a set of conductive paths 183 (e.g., metal wiring layers). In specific embodiments, conductive paths 183 may couple the set of shared substrate connections 171, 172, 173, and 174 to an external set of connections 119. In specific embodiments, the set of external connections 119 may be provided as part of a package for the system. In specific embodiments, the set of external connections 119 may be package contacts.

Chiplet connections (e.g., 167 and 168), shared substrate connections (e.g., 171, 172, 173, and 174), and external connections (e.g., 119) may be connected in different combinations. In specific embodiments, each chiplet connection is connected to a shared substrate connection. In specific embodiments, each chiplet connection is connected to an external connection (e.g., via a shared substrate connection). In specific embodiments, one or more chiplet connections may not be (e.g., may refrain from being) connected to a shared substrate connection or an external connection. In specific embodiments, one or more external connections may not be (e.g., may refrain from being) connected to a shared substrate connection or a chiplet connection. In specific embodiments, one or more shared substrate connections may not be (e.g., may refrain from being) connected to an external connection or a chiplet connection. That is, some connections (chiplet connections, shared substrate connections, and/or external connections) may be unused.

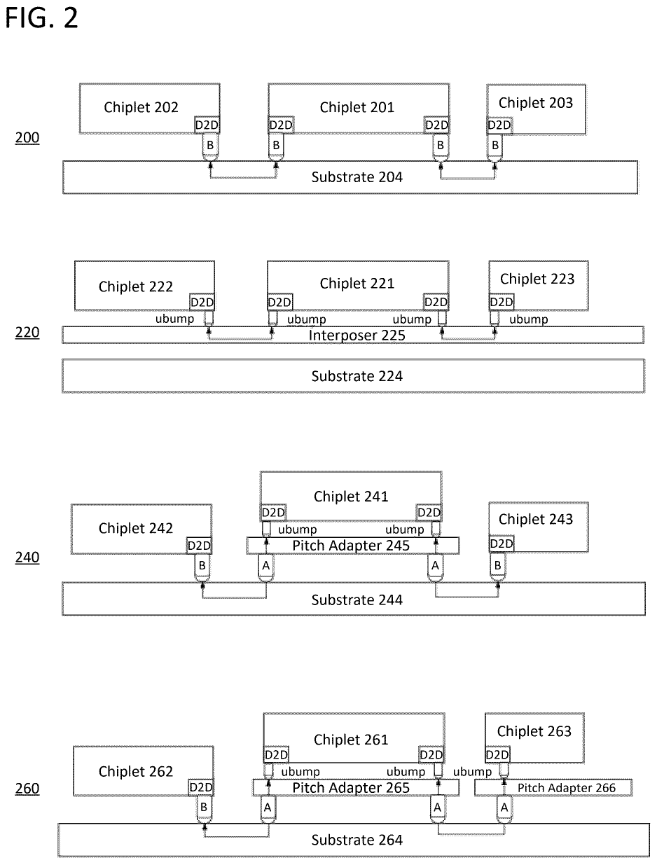

FIG. 2 illustrates different packaging configurations for chiplets in accordance with specific embodiments of the inventions disclosed herein. The diagram depicts four distinct arrangements: standard package 200, advanced package 220 with a full redistribution layer (RDL), advanced package 240 with a discrete pitch adapter substrate (e.g., a simplified RDL) on one chiplet, and advanced package 260 with a discrete pitch adapter substrate for each of two chiplets.

In standard package 200, chiplets 201, 202, and 203 are arranged on substrate 204. Each chiplet includes a die connection interface (D2D) that connects to substrate 204 through connection points labeled “B”. The die connection interface may be a set of conductive pads or bumps on the surface of the chiplet that allow for electrical connections to be made. Each chiplet may have die pads that connect to the bumps under the chiplet. Substrate 204 may be shared by chiplets 201, 202, and 203. Chiplets 201, 202, and 203 may have coarse pitches that lead to low bandwidth communication between themselves or other components.

Advanced package 220 with the full RDL configuration displays chiplets 221, 222, and 223, each with a die connection interface. In this arrangement, the chiplets connect to an interposer layer through microbump (ubump) arrays. A microbump array may be a dense array of small conductive bumps used for high-density chip-to-chip or chip-to-substrate connections. Interposer 225 (e.g., interposer layer) sits between the chiplets and substrate 224, providing a means to redistribute the connections from the fine pitch of the chiplets 221, 222, and 223 to a coarser pitch that can be accommodated by substrate 224. Substrate 224 may be shared by chiplets 221, 222, and 223. Interposer 225 may be a routing layer from chiplets 221, 222, and 223, may have a limited number of layers, and may only be used to convert from one pitch to another (e.g., may not include computational circuitry).

Advanced package 240 with a discrete pitch adapter configuration shows chiplets 241, 242, and 243 arranged with a simplified interposer structure. Chiplet 241 includes two die connection interfaces connected to discrete pitch adapter substrate 245 through microbump arrays. In specific embodiments, discrete pitch adapter substrate 245 may be considered a simplified interposer. Discrete pitch adapter substrate 245 may be a routing layer that matches (e.g., with a 0 mm to 5 mm overhang) the footprint of chiplet 241, has a limited number of layers, and may only be used to convert from one pitch to another (e.g., may not include computational circuitry or any supra-physical-layer signal processing circuitry). Discrete pitch adapter substrate 245 may connect to substrate 244 using connections labeled “A”. Chiplets 242 and 243 maintain their die connection interfaces with direct connections labeled “B” to substrate 244. Connections “A” and “B” may be two different variations of bumps. Substrate 244 may be shared by chiplets 241, 242, and 243.

In specific embodiments, discrete pitch adapter substrate 245 may be electrically coupled to chiplet 241 via a first set of chiplet connections. The first set of chiplet connections may directly couple a first chiplet-adapter interface of pitch adapter substrate 245 with chiplet 241. The first chiplet-adapter interface of discrete pitch adapter substrate 245 may have a first pitch, which may match the pitch of chiplet 241.

Discrete pitch adapter substrate 245 may be electrically coupled to substrate 244 via a set of substrate connections. In some cases, the set of substrate connections may directly couple a first adapter-substrate interface of discrete pitch adapter substrate 245 with substrate 244. The adapter-substrate interface of the pitch adapter substrate 265 may have a substrate pitch, which may be different than the microbump pitch between chiplet 241 and discrete pitch adapter substrate 245. This substrate pitch may match the pitch of the shared substrate 244, allowing for a uniform connection interface across different chiplets with varying pitches.

Advanced package 260 has a discrete pitch adapter configuration for each of chiplet 261 and chiplet 263. Chiplets 261, 262, and 263 may be arranged with a simplified interposer structure. Chiplet 261 includes two die connection interfaces connected to discrete pitch adapter substrate 265 through microbump arrays. In specific embodiments, discrete pitch adapter substrate 265 may be considered a simplified interposer. Discrete pitch adapter substrate 265 may be a routing layer that matches (e.g., with a 0 mm to 5 mm overhang) the footprint of chiplet 261, has a limited number of layers, and may only be used to convert from one pitch to another (e.g., may not include computational circuitry). Discrete pitch adapter substrate 265 may connect to substrate 264 using connections labeled “A”. Chiplet 263 includes two die connection interfaces connected to discrete pitch adapter substrate 266 through microbump arrays. In specific embodiments, discrete pitch adapter substrate 266 may be considered a simplified interposer. Discrete pitch adapter substrate 266 may be a routing layer that matches (e.g., with a 0 mm to 5 mm overhang) the footprint of chiplet 263, has a limited number of layers, and may only be used to convert from one pitch to another (e.g., may not include computational circuitry). Discrete pitch adapter substrate 266 may connect to substrate 264 using connections labeled “A”. Chiplet 262 maintains its die connection interfaces with direct connections labeled “B” to substrate 264. Connections “A” and “B” may be two different variations of bumps. Substrate 264 may be shared by chiplets 261, 262, and 263.

In specific embodiments, discrete pitch adapter substrate 245 may be electrically coupled to chiplet 261 via a first set of chiplet connections. The first set of chiplet connections may directly couple a first chiplet-adapter interface of pitch adapter substrate 265 with chiplet 261. The first chiplet-adapter interface of discrete pitch adapter substrate 265 may have a first pitch, which may match the pitch of chiplet 261.

In specific embodiments, pitch adapter substrate 266 may be electrically coupled to chiplet 263 via a second set of chiplet connections. The second set of chiplet connections may directly couple a chiplet-adapter interface of discrete pitch adapter substrate 266 with chiplet 263. Chiplet 263 may have a pitch that is different than the pitch of chiplet 261.

Each pitch adapter substrate may be electrically coupled to shared substrate 264 via sets of substrate connections. In some cases, a first set of substrate connections may directly couple a first adapter-substrate interface of discrete pitch adapter substrate 265 with shared substrate 264. Similarly, a second set of substrate connections may directly couple a second adapter-substrate interface of pitch adapter substrate 266 with shared substrate 264.

The adapter-substrate interfaces of the pitch adapter substrates 265 and 266 may have a third pitch, which may be different than the first pitch (the microbump pitch between chiplet 261 and discrete pitch adapter substrate 265) and the second pitch (the microbump pitch between chiplet 263 and discrete pitch adapter substrate 266). This third pitch may match the pitch of the shared substrate 264, allowing for a uniform connection interface across different chiplets with varying pitches.

Discrete pitch adapter substrates may allow larger bandwidth compared to standard packaging and cheaper manufacturing compared to full interposers or RDLs. Chiplets may include fine pitches so to allow a larger number of connections between two chiplets (or a chiplet and other circuitry). Systems may include multiple chiplets having different pitch sizes; discrete pitch adapter substrates allow this mix and match while still taking advantage of the higher bandwidth from the higher connection count. A discrete pitch adapter substrate may convert a fine pitch to a coarse pitch, such that all chiplets in the system have the same pitch and can be processed together on the same substrate. Even with high variance in initial chiplet pitches, the system may provide the high bandwidth of the initial fine pitches.

Discrete pitch adapter substrates may combine high bandwidth and low cost. In standard package 200, chiplet 201 may be 1 mm (e.g., into the page), resulting in room for seven connections (e.g., wires) where the wires coming out of chiplet 201 have a pitch of about a 10 um. In advanced package 220, chiplet 221 may be 1 mm (e.g., into the page) with a higher pitch such that chiplet 221 has 30 connections that have a pitch of about 1 um, resulting in higher bandwidth. In specific embodiments, a 1 um pitch is small enough to require the use of an interposer. However, full interposer 225 may be unnecessary for chiplets 222 and 223, which may not have as fine pitches and may be capable of interfacing directly with substrate 244. In this case, the extra interposer space is an unnecessary cost. Chiplets using discrete pitch adapter substrates may match the high bandwidth of chiplets using full interposers at a fraction of the cost. For example, a full interposer may cost around $100 while a discrete pitch adapter substrate (e.g., one that is 25×16 mm) may be $15-20. The cost of discrete pitch adapter substrates may depend on size, but may still be much cheaper than a full interposer. The decreased cost may be due to a smaller area and a smaller number of layers in the discrete pitch adapter substrate.

Discrete pitch adapter substrates, such as discrete pitch adapter substrates 245, 265, and 266 may be cheaper and easier to manufacture. Additionally, discrete pitch adapter substrates provide flexibility to mix and match different chiplets with large differences in pitches. Die to die interface distribution on the bottom of chiplets varies. Different protocols, placements, sizes, and quantity D2D interfaces may affect the suitability of an interposer; different chiplets may require different interposer designs and this may easily be achieved using discrete pitch adapter substrates. By using discrete pitch adapter substrates, chiplets with different connection pitches can be integrated onto the same package. This approach provides flexibility in chiplet selection and integration, potentially allowing for more efficient use of space and improved overall system performance.

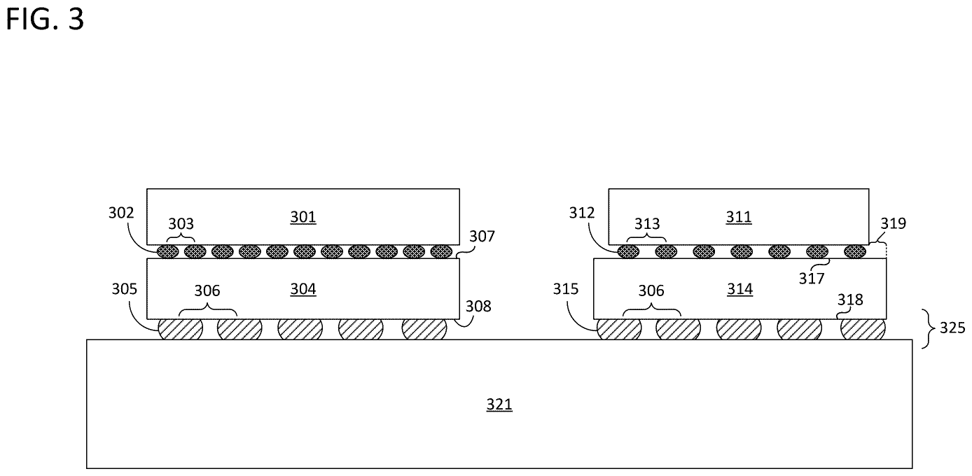

FIG. 3 illustrates examples of discrete pitch adapter substrates adapting chiplet connection pitches to the shared substrate pitch in accordance with specific embodiments of the inventions disclosed herein. A system may include multiple chiplets connected to a substrate via multiple discrete adapter substrate. The system may also include one or more chiplets connected directly to the substrate without the use of a discrete adapter substrate. Each discrete pitch adapter substrate may be unique to a chiplet, in that the discrete pitch adapter substrates are coupled with a chiplet in a one-to-one ratio. The discrete pitch adapter substrate may be custom made for that chiplet and that substrate, as chiplets and substrates may each use a variety of different pitches and have a variety of different sizes. In specific embodiments, the system may include one or more chiplets without (e.g., not associated with any) discrete pitch adapter substrate. Chiplets may be unpackaged integrated circuits. For example, chiplets 301 and 311 may be silicon chiplets with all their circuitry.

Chiplets 301 and 311 may be electrically connected to the same substrate 321 via set of shared substrate connections 325. Each chiplet 301 and 311 may have a set of chiplet connections 302 and 312, respectively. Chiplet connections 302 may have pitch 303 which may be different than (e.g., unique from) pitch 313 of chiplet connections 312. In specific embodiments, there may be multiple chiplets on substrate 321 with chiplet connections having the same pitch. For example, another chiplet (not shown) may also have pitch 303. Pitch 306 of set of shared substrate connections 325 may be different than pitches 303 and 313 of chiplet connections 302 and 312. Set of shared substrate connections 325 may be bumps; chiplet connections 302 and 312 may be microbumps.

The system may include a plurality of discrete pitch adapter substrates, each discrete pitch adapter substrate being uniquely associated with a chiplet in the plurality of chiplets. For example, chiplet 301 may be associated with (e.g., be coupled with) discrete pitch adapter substrate 304 and chiplet 311 may be associated with (e.g., be coupled with) a different discrete pitch adapter substrate 314. The pitch adapter substrates may be discrete in that they are physically separate components. The discrete pitch adapter substrates may be physically touching (directly or via a packaging material), however, the pitch adapter substrates may be manufactured as separate components or have been split apart at some point in the manufacturing process. In specific embodiments, discrete pitch adapter substrates may be electrically isolated from each other or may be electrically connected via metal wiring layers in the substrate. In specific embodiments, discrete pitch adapter substrates may not be directly electrically connected to each other (e.g., any conductive path between discrete pitch adapters may go through the substrate).

Each discrete pitch adapter substrate may comprise a set of conductive paths (e.g., set of metal wiring layers). Each discrete pitch adapter substrate may connect (e.g., couple) the set of chiplet connections of the uniquely associated chiplet to the set of shared substrate connections. For example, discrete pitch adapter substrate 304 may connect the set of chiplet connections 302 of chiplet 301 to the set of shared substrate connections 325 via substrate connections 305 while discrete pitch adapter substrate 314 may connect the set of chiplet connections 312 of chiplet 311 to the set of shared substrate connections 305 via substrate connections 315.

Discrete pitch adapter substrate 304 may be electrically coupled to chiplet 301 via a first set of chiplet connections. Chiplet-adapter interface 307 of discrete pitch adapter substrate 304 may have pads with pitch 303. Chiplet 301 may also have pads with pitch 303. The first set of chiplet connections may directly couple chiplet-adapter interface 307 with chiplet 301. Discrete pitch adapter substrate 314 may be electrically coupled to chiplet 311 via a second set of chiplet connections 312. Chiplet-adapter interface 317 of discrete pitch adapter substrate 314 may have pads with pitch 313. Chiplet 311 may also have pads with pitch 313. Pitch 313 may be different than pitch 303. The second set of chiplet connections may directly couple chiplet-adapter interface 317 with chiplet 311.

Discrete pitch adapter substrate 304 may be electrically coupled to shared substrate 321 via set of substrate connections 305. Adapter-substrate interface 308 of discrete pitch adapter substrate 304 may have pads with pitch 306. Substrate 321 may have pads with pitch 306. Pitch 306 may be different than pitch 303 and pitch 313. Set of substrate connections 305 may directly couple adapter-substrate interface 308 with shared substrate 321. Discrete pitch adapter substrate 314 may be electrically coupled to shared substrate 321 via a second set of substrate connections 315. Adapter-substrate interface 318 of discrete pitch adapter substrate 314 may have pads with pitch 306 (e.g., the same as the pitch of adapter-substrate interface 308). Set of substrate connections 315 may directly couple adapter-substrate interface 318 with shared substrate 321.

Substrate 321 may include a set of metal wiring layers. In specific embodiments, the set of metal wiring layers of substrate 321 may couple the set of shared substrate connections 325 to an external set of connections. In specific embodiments, the set of external connections may be provided as part of a package for the system. In specific embodiments, the set of external connections may be package contacts. Substrate 321 may be composed of silicon or another suitable material such as silicon carbide and gallium nitride.

Chiplet connections 302 and 312, shared substrate connections 325, and external connections may be connected in different combinations. In specific embodiments, each chiplet connection is connected to a shared substrate connection. In specific embodiments, each chiplet connection is connected to an external connection (e.g., via a shared substrate connection). In specific embodiments, one or more chiplet connections may not be (e.g., may refrain from being) connected to a shared substrate connection or an external connection. In specific embodiments, one or more external connections may not be (e.g., may refrain from being) connected to a shared substrate connection or a chiplet connection. In specific embodiments, one or more shared substrate connections may not be (e.g., may refrain from being) connected to an external connection or a chiplet connection. That is, some connections (chiplet connections, shared substrate connections, and/or external connections) may be unused.

In specific embodiments, discrete pitch adapter substrates may be designed to closely match (e.g., be within a few millimeters of) the footprint size of its associated chiplet. For example, a footprint size of discrete pitch adapter substrate 304 may have an overhang of 0 mm to 5 mm compared to a footprint size of chiplet 301 (FIG. 3 shows the footprint sizes as being the same with 0 mm of overhang). Additionally, a footprint size of discrete pitch adapter substrate 314 may have an overhang of 0 mm to 5 mm compared to a footprint size of chiplet 311. FIG. 3 shows the footprint size of discrete pitch adapter substrate 314 as being a little larger than chiplet 311 with nonzero overhang 319.

Using the minimum size of a given assembly process may be desirable to reduce costs. In specific embodiments, the discrete pitch adapter substrate may be minimized to match the chiplet size in order to minimize cost and improve assembly. A 0 mm overhang may be desirable and achievable with some assembly processes. Other small overhang distances, such as an overhang of 1 mm, may be possible with other assembly processes. For example, overhang 319 may be between 0 and 5 mm. An overhang of more than 5 mm may be considered wasteful in terms of cost and assembly complications. A range of approximately 0 mm overhang to 5 mm overhang may be achieved by various assembly process constraints.

This close size correspondence may allow for efficient use of package space and simplify the overall package design. The similar footprint sizes may also facilitate easier alignment and assembly processes during manufacturing. In some cases, matching the footprint sizes closely may help maintain signal integrity by minimizing the length of interconnects between the chiplet and the discrete pitch adapter substrate. Additionally, having closely matched footprints may provide thermal management benefits by allowing for more uniform heat distribution across the package.

In specific embodiments, the 0 mm to 5 mm overhang correspondence is only an example, as in specific embodiments a footprint size of a discrete pitch adapter substrate may be smaller or larger than a footprint size of the corresponding chiplet by any amount as long as the discrete pitch adapter substrate is uniquely associated with the chiplet in a one-to-one correspondence. In specific embodiments, the chiplets may have unique pitches.

In specific embodiments, the discrete pitch adapter substrates may be selected from a library of discrete pitch adapter substrates. The discrete pitch adapter substrates in the library of discrete pitch adapter substrates may be configured to convert different starting pitches to different ending pitches. Starting pitches may be designed for (e.g., to connect to) chiplets, while ending pitches may be designed for (e.g., to connect to) shared substrate connections. Accordingly, starting pitches may be finer than ending pitches. The library may include one or more discrete pitch adapter substrates with a starting pitch of Pitch I and an ending pitch of Pitch III and one or more discrete pitch adapter substrates with a starting pitch of Pitch II and an ending pitch of Pitch III. The library may include a variety of combinations of pitches. For example, a discrete pitch adapter substrate in the library may have a starting pitch of Pitch IV (different than Pitches I, II, and III) and an ending pitch of Pitch III. Another discrete pitch adapter substrate may have a starting pitch of Pitch IV and an ending pitch of Pitch V (different than Pitches I, II, III, and IV). Another discrete pitch adapter substrate may have a starting pitch of Pitch I and an ending pitch of Pitch V. The specific discrete pitch adapter substrates chosen for a system may be based on (e.g., to align with) the pitches of the chiplet connections and the shared substrate connection of the system.

Discrete pitch adapter substrates in the library may have different quantities of connections. For example, the discrete pitch adapter substrate for a first chiplet a may connect eleven chiplet connections (Pitch I) and five shared substrate connections (Pitch III). A second discrete pitch adapter substrate of the library may connect fifteen chiplet connections (Pitch I) and six shared substrate connections (Pitch III). A third discrete pitch adapter substrate of the library may connect five chiplet connections (Pitch I) and two shared substrate connections (Pitch III). Additionally, discrete pitch adapter substrates may have different form factors, even if the same quantities of connections are used. Discrete pitch adapter substrates may be chosen from the library based on the application and requirements of the system, including the pitches, quantity of connections, and form factors of the chiplet connections and shared substrate connections. Discrete pitch adapter substrates may be different sizes to accommodate different sizes of chiplets.

A method of packaging a system in accordance with specific embodiments of the inventions disclosed herein may be implemented by a system including one or more chiplets and one or more discrete pitch adapter substrates. The method may be implemented by a system including means for performing the steps of the method. Steps, or portions of steps, of the method may be duplicated, omitted, rearranged, or otherwise deviate from the form shown. The method may include selecting a first discrete pitch adapter substrate from a library of discrete pitch adapter substrates based on a first pitch of a set of chiplet connections of a first chiplet and a second pitch of a set of shared substrate connections, the set of shared substrate connections may be connected to a set of metal wiring layers of a substrate. The method may include selecting a second discrete pitch adapter substrate from the library of discrete pitch adapter substrates based on a third pitch of a set of chiplet connections of a second chiplet and the second pitch of the set of shared substrate connections. The method may include coupling the first chiplet to the set of shared substrate connections via the first discrete pitch adapter substrate. The method may include coupling the second chiplet to the set of shared substrate connections via the second discrete pitch adapter substrate. The first pitch, the second pitch, and the third pitch may be different. The discrete pitch adapter substrates in the library of discrete pitch adapter substrates may be configured to connect to different pitches of chiplet connections.

By using the systems and methods to use discrete pitch adapter substrates (e.g., simplified RDLs) to convert any connection pitch to another pitch, the use of chiplets of very different connection pitches on the same package may be enabled. Discrete pitch adapter substrates may enable the use of chiplets of different bump pitches on the same package without the need for length expensive silicon re-spins. The discrete pitch adapter substrates also reduce the cost and lead-time of advanced package.

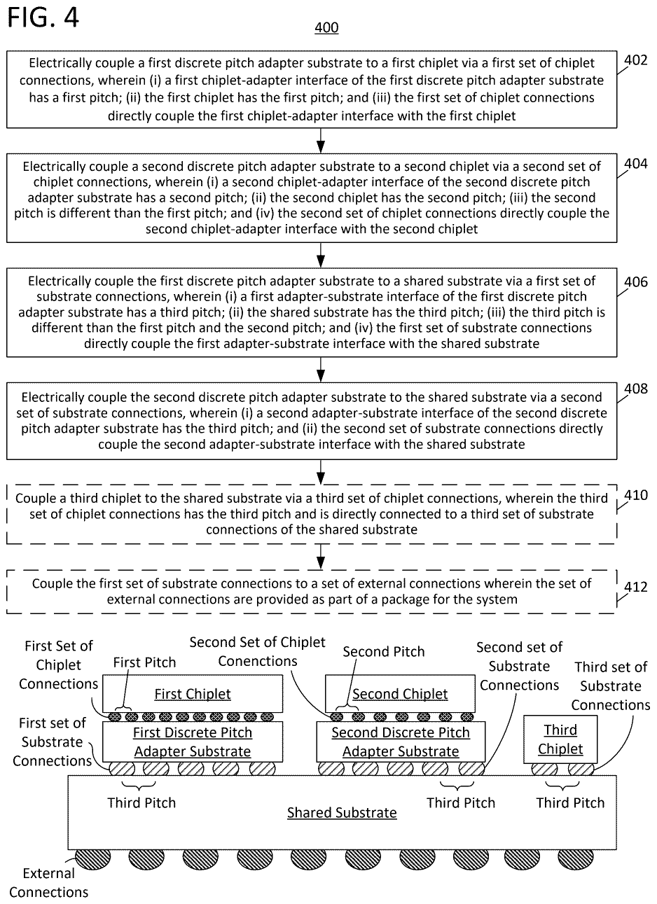

FIG. 4 provides an example of method 400 of packaging a system with discrete pitch adapter substrates in accordance with specific embodiments of the inventions disclosed herein. Method 400 may be implemented by a system including one or more chiplets and one or more discrete pitch adapter substrates. In specific embodiments, the system may also include a substrate and a PCB. Method 400 may be implemented by a system including means for performing the steps of method 400. Steps, or portions of steps, of method 400 may be duplicated, omitted, rearranged, or otherwise deviate from the form shown. Additional steps may be added to method 400. Steps, or portions of steps, of method 400 may be performed in series or parallel.

At step 402, a first discrete pitch adapter substrate may be electrically coupled to a first chiplet via a first set of chiplet connections. A first chiplet-adapter interface of the first discrete pitch adapter substrate may have a first pitch. The first chiplet may have the first pitch. The first set of chiplet connections may directly couple the first chiplet-adapter interface with the first chiplet. In specific embodiments, the first set of chiplet connections may be microbumps. In specific embodiments, a footprint size of the first discrete pitch adapter substrate may have an overhang of between 0 mm and 5 mm compared toa footprint size of the first chiplet. Using the minimum manufacturable size of a discrete pitch adapter substrate for a given assembly process may be desirable. In specific embodiments, the first discrete pitch adapter substrate may be minimized to match the first chiplet size in order to minimize cost and improve assembly. A 0 mm to 5 mm overhang may be achievable with some assembly processes. An overhang of more than 5 mm may be considered wasteful in terms of cost and assembly complications.

At step 404, a second discrete pitch adapter substrate may be electrically coupled to a second chiplet via a second set of chiplet connections. A second chiplet-adapter interface of the second discrete pitch adapter substrate may have a second pitch. The second chiplet may have the second pitch. The second pitch may be different than the first pitch. The second set of chiplet connections may directly couple the second chiplet-adapter interface with the second chiplet. In specific embodiments, the second set of chiplet connections may be microbumps. In specific embodiments, a footprint size of the second discrete pitch adapter substrate may have an overhang of between 0 mm and 5 mm compared to of a footprint size of the second chiplet.

At step 406, the first discrete pitch adapter substrate may be electrically coupled to a shared substrate via a first set of substrate connections. A first adapter-substrate interface of the first discrete pitch adapter substrate may have a third pitch. The shared substrate may have the third pitch. The third pitch may be different than the first pitch and the second pitch. The first set of substrate connections may directly couple the first adapter-substrate interface with the shared substrate. In specific embodiments, the shared substrate may include a structural core and neither the first discrete pitch adapter substrate nor the second discrete pitch adapter substrate may include a structural core. In specific embodiments, at least one shared substrate connection of the first set of substrate connections may be connected to more than one chiplet connection of the first set of chiplet connections. In specific embodiments, the first set of substrate connections may be bumps.

At step 408, the second discrete pitch adapter substrate may be electrically coupled to the shared substrate via a second set of substrate connections. A second adapter-substrate interface of the second discrete pitch adapter substrate may have the third pitch. The second set of substrate connections may directly couple the second adapter-substrate interface with the shared substrate. In specific embodiments, the second set of substrate connections may be bumps. In specific embodiments, the shared substrate may include a third set of substrate connections that is not connected to the first set of chiplet connections or the second set of chiplet connections. The first, second, and third sets of substrate connections may be subsets of a set of shared substrate connections.

In specific embodiments, at step 410, a third chiplet may be coupled to the shared substrate via a third set of chiplet connections. The third set of chiplet connections may have the third pitch and may be directly connected to a third set of substrate connections of the shared substrate. In specific embodiments, the third set of chiplet connections may be bumps.

In specific embodiments, at step 412, the first set of substrate connections may be coupled to a set of external connections. The set of external connections may be provided as part of a package for the system. In specific embodiments, the set of external connections may be package contacts.

By using the systems and methods to use discrete pitch adapter substrates (e.g., simplified RDLs) to convert any connection pitch to another pitch, the use of chiplets of very different connection pitches on the same package may be enabled. Discrete pitch adapter substrates may enable the use of chiplets of different bump pitches on the same package without the need for length expensive silicon re-spins. The discrete pitch adapter substrates also reduce the cost and lead-time of advanced package.

While the specification has been described in detail with respect to specific embodiments of the invention, it will be appreciated that those skilled in the art, upon attaining an understanding of the foregoing, may readily conceive of alterations to, variations of, and equivalents to these embodiments. For example, while the specification referred to chiplets, any form of integrated circuit can be used in place of the chiplets in these examples in accordance with the approaches disclosed herein. These and other modifications and variations to the present invention may be practiced by those skilled in the art, without departing from the scope of the present invention, which is more particularly set forth in the appended claims.

What is claimed is:

1. A system comprising:
a first chiplet with a first set of chiplet connections having a first pitch;
a second chiplet with a second set of chiplet connections having a second pitch, the second pitch being different than the first pitch;
a first discrete pitch adapter substrate comprising a first set of conductive paths, wherein the first set of conductive paths connects the first set of chiplet connections to a set of shared substrate connections, the set of shared substrate connections having a third pitch different than the first pitch and the second pitch; and
a second discrete pitch adapter substrate comprising a second set of conductive paths, wherein the second set of conductive paths connects the second set of chiplet connections to the set of shared substrate connections.

2. The system of claim 1, further comprising:
a third chiplet with a third set of chiplet connections having the third pitch and directly connected to the set of shared substrate connections.

3. The system of claim 2, wherein:
the first set of chiplet connections are microbumps; and
the third set of chiplet connections are bumps.

4. The system of claim 1, further comprising:
a substrate that includes the set of shared substrate connections;
wherein the substrate includes a structural core and neither the first discrete pitch adapter substrate nor the second discrete pitch adapter substrate includes a core.

5. The system of claim 1, wherein:
a footprint size of the first discrete pitch adapter substrate has an overhang of between 0 mm and 5 mm compared to a footprint size of the first chiplet.

6. The system of claim 1, wherein a subset of the set of shared substrate connections is not connected to a subset of the first set of chiplet connections.

7. The system of claim 1, wherein at least one shared substrate connection of the set of shared substrate connections is connected to more than one chiplet connection of the first set of chiplet connections.

8. The system of claim 1, wherein:
the first set of chiplet connections are microbumps;
the second set of chiplet connections are microbumps; and
the set of shared substrate connections are bumps.

9. The system of claim 1, further comprising:
a substrate that includes the set of shared substrate connections; and
a printed circuit board;
wherein a third set of conductive paths in the substrate connects the set of shared substrate connections with the printed circuit board.

10. A method of packaging a system comprising:
electrically coupling a first discrete pitch adapter substrate to a first chiplet via a first set of chiplet connections, wherein (i) a first chiplet-adapter interface of the first discrete pitch adapter substrate has a first pitch; (ii) the first chiplet has the first pitch; and (iii) the first set of chiplet connections directly couple the first chiplet-adapter interface with the first chiplet;
electrically coupling a second discrete pitch adapter substrate to a second chiplet via a second set of chiplet connections, wherein (i) a second chiplet-adapter interface of the second discrete pitch adapter substrate has a second pitch; (ii) the second chiplet has the second pitch; (iii) the second pitch is different than the first pitch; and (iv) the second set of chiplet connections directly couple the second chiplet-adapter interface with the second chiplet;
electrically coupling the first discrete pitch adapter substrate to a shared substrate via a first set of substrate connections, wherein (i) a first adapter-substrate interface of the first discrete pitch adapter substrate has a third pitch; (ii) the shared substrate has the third pitch; (iii) the third pitch is different than the first pitch and the second pitch; and (iv) the first set of substrate connections directly couple the first adapter-substrate interface with the shared substrate; and
electrically coupling the second discrete pitch adapter substrate to the shared substrate via a second set of substrate connections, wherein (i) a second adapter-substrate interface of the second discrete pitch adapter substrate has the third pitch; and (ii) the second set of substrate connections directly couple the second adapter-substrate interface with the shared substrate.

11. The method of claim 10, further comprising:
coupling the first set of substrate connections to a set of external connections wherein the set of external connections are provided as part of a package for the system.

12. The method of claim 11, wherein the set of external connections are package contacts.

13. The method of claim 10, further comprising:
coupling a third chiplet to the shared substrate via a third set of chiplet connections, wherein the third set of chiplet connections has the third pitch and is directly connected to a third set of substrate connections of the shared substrate.

14. The method of claim 13, wherein:
the first set of chiplet connections are microbumps; and
the third set of chiplet connections are bumps.

15. The method of claim 10, wherein the shared substrate includes a structural core and neither the first discrete pitch adapter substrate nor the second discrete pitch adapter substrate includes a structural core.

16. The method of claim 10, wherein a footprint size of the first discrete pitch adapter substrate has an overhang of between 0 mm and 5 mm compared to a footprint size of the first chiplet.

17. The method of claim 10, wherein the shared substrate includes a third set of substrate connections that is not connected to the first set of chiplet connections or the second set of chiplet connections.

18. The method of claim 10, wherein at least one shared substrate connection of the first set of substrate connections is connected to more than one chiplet connection of the first set of chiplet connections.

19. The method of claim 10, wherein:
the first set of chiplet connections are microbumps;
the second set of chiplet connections are microbumps; and
the first set of substrate connections are bumps.

20. A system comprising:
a plurality of chiplets, each chiplet of the plurality of chiplets having a set of chiplet connections with a unique pitch, wherein the unique pitch of each chiplet of the plurality of chiplets is different;
a set of shared substrate connections, a pitch of the set of shared substrate connections being different than the unique pitches of the plurality of chiplets;
a plurality of discrete pitch adapter substrates, each discrete pitch adapter substrate being uniquely associated with a chiplet in the plurality of chiplets, wherein: (i) each discrete pitch adapter substrate comprises a set of conductive paths; (ii) each discrete pitch adapter substrate connects the set of chiplet connections of the uniquely associated chiplet to the set of shared substrate connections; and
a substrate comprising a set of metal wiring layers, wherein the set of metal wiring layers of the substrate couples the set of shared substrate connections to an external set of connections.
